(19) United States
(12) Patent Application Publication
(10) Pub. No.: US 2014/0106511 A1
(43) Pub. Date: Apr. 17, 2014

(54) FLIP-CHIP PACKAGING TECHNIQUES AND CONFIGURATIONS

(71) Applicant: TriQuint Semiconductor, Inc., Hillsboro, OR (US)

(72) Inventors: Frank J. Juskey, Apopka, FL (US); Robert C. Hartmann, Apopka, FL (US); Paul D. Bantz, Los Altos, CA (US)

(73) Assignee: TriQuint Semiconductor, Inc., Hillsboro, OR (US)

(21) Appl. No.: 14/108,093

(22) Filed: Dec. 16, 2013

Related U.S. Application Data
(62) Division of application No. 13/413,595, filed on Mar. 6, 2012.

(51) Int. Cl. H01L 23/00

(52) U.S. Cl. CPC H01L 24/81
USPC 438/126

(57) ABSTRACT

Embodiments of the present disclosure flip-chip packaging techniques and configurations. An apparatus may include a package substrate having a plurality of pads formed on the package substrate, the plurality of pads being configured to receive a corresponding plurality of interconnect structures formed on a die and a fluxing underfill material disposed on the package substrate, the fluxing underfill material comprising a fluxing agent configured to facilitate formation of solder bonds between individual interconnect structures of the plurality of interconnect structures and individual pads of the plurality of pads and an epoxy material configured to harden during formation of the solder bonds to mechanically strengthen the solder bonds. Other embodiments may also be described and/or claimed.

### RELATED APPLICATIONS

This application is a divisional of and claims priority to U.S. patent application Ser. No. 13/413,595 entitled “Flip-Chip Packaging Techniques and Configurations,” filed on 6-Mar.-2012, the entire disclosure of which is incorporated herein by reference.

### FIELD

Embodiments of the present disclosure generally relate to the field of integrated circuit packages, and more particularly, to flip-chip packaging techniques and configurations.

### BACKGROUND

Integrated circuit (IC) packages may include a variety of components (e.g., dies and/or passive components) coupled with a package substrate using solderable material. For example, solder joints may be formed to electrically and/or mechanically couple the components to a package substrate. The solder joints may fail (e.g., crack or break) when exposed to elevated temperatures associated with thermal processes such as solder reflow or molding processes or when subjected to handling by equipment or customers. Thermal failures may be due, in part, to different rates of expansion/contraction associated with different materials of an integrated circuit package. For example, materials of the die and the package substrate may have different thermal coefficients of expansion (TCE) resulting in different rates of expansion/contraction during heating/cooling associated with thermal processes.

Furthermore, in conventional transfer molding techniques, a die may be fully encapsulated on a package substrate such that molding material is in direct physical contact with the package substrate. Formation of the molding may produce voids that allow solder migration causing electrical failures or that trap moisture. The moisture may explode or otherwise exert pressure when temperatures of the moisture in the voids is elevated (e.g., above the boiling point of the moisture). Such explosions and/or exertion of pressure may cause shorting and/or other failures of the die by, for example, causing failure of interconnects or solder joints between the die and package substrate.

Additionally, current techniques to form IC packages may include one or more cleaning operations to clean a surface of the package substrate (e.g., remove flux residue at or near the solder joint region) to provide a clean surface for a molding process that forms a molding to encapsulate the components and couple with the package substrate. The cleaning operation(s) may add cost and/or time to a manufacturing process used to fabricate the IC packages.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) package configuration including a fluxing underfill material and a sheet molding structure, according to various embodiments.

FIG. 2 schematically illustrates a cross-section side view of another example IC package configuration including a fluxing underfill material and a sheet molding structure, according to various embodiments.

FIG. 3 schematically illustrates a cross-section side view of another example IC package configuration including a fluxing underfill material and a tape structure, according to various embodiments.

FIG. 4 schematically illustrates a cross-section side view of another example IC package configuration including a fluxing underfill material and a sheet molding structure, according to various embodiments.

FIG. 5 is a flow diagram of a method for fabricating an IC package as described herein, according to various embodiments.

FIG. 6 schematically illustrates an example system including an IC package, according to various embodiments.

### DETAILED DESCRIPTION

Embodiments of the present disclosure describe flip-chip packaging techniques and configurations. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The description may use perspective-based descriptions such as over/under, back/front, or top/bottom. Such descriptions are merely used to facilitate the discussion and are not intended to restrict the application of embodiments described herein to any particular orientation.

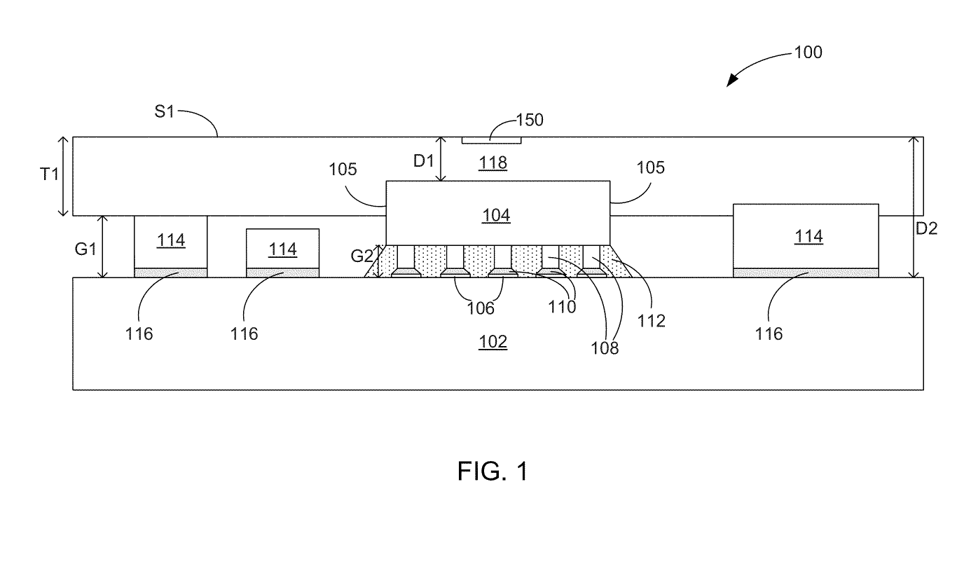

FIG. 1 schematically illustrates a cross-section side view of an example integrated circuit (IC) package 100 configuration including a fluxing underfill material 112 and a sheet molding structure 118, according to various embodiments. The IC package 100 includes a package substrate such as a printed circuit board (PCB) 102 and one or more components mounted on a surface of the PCB 102.

The one or more components can include, for example, one or more dies (hereinafter die 104) that are coupled with the PCB 102 in a flip-chip configuration, as can be seen. In the flip-chip configuration an active surface (e.g., a surface having electronic devices formed thereon) of the die 104 is coupled with PCB 102 using interconnect structures 108 formed on the active surface.

According to various embodiments, the die 104 may include active and/or passive components. The die 104 may represent a surface acoustic wave (SAW) device, a bulk acoustic wave (BAW) device, a gallium arsenide (GaAs) device, a gallium nitride (GaN) device, and/or a radio frequency (RF) die for wireless communication, however, subject matter is not limited in this regard. The die may comprise a switch flip-chip such as, for example, a single-pole, four-throw (SP4T) switch. In other embodiments, the die 104 may represent any suitable semiconductor die including, for example, a processor die and/or memory die.

The one or more components mounted on the PCB 102 may further include one or more passive components (hereinafter passive components 114). The passive components 114 may include, for example, capacitors, inductors, resistors, transformers, or filters. The passive components 114 may include other types of devices in other embodiments.

According to various embodiments, the die 104 and/or the passive components 114 are electrically and/or mechanically coupled with the PCB 102 using one or more solder bonds (e.g., solder bonds 116 or solder bonds 110) that are formed using a solderable material. For example, in some embodiments, the passive components 114 may be coupled with the PCB 102 using solder bonds 116 formed of solder paste. A solder paste may include a mixture of a fluxing agent and a solderable material. The solderable material for the solder bonds 110 and 116 may include, for example, tin, silver, gold, copper, lead, antimony, or alloys thereof. The solder bonds 110 and 116 may be formed using other solderable materials in other embodiments.

In some embodiments, the PCB 102 may include a plurality of pads (hereinafter pads 106) formed on the PCB 102. The pads 106 may be configured to receive a corresponding plurality of interconnect structures (hereinafter interconnect structures 108) formed on the die 104, as can be seen. The interconnect structures 108 of the die 104 may be electrically and/or mechanically coupled with the pads 106 of the PCB 102 using the solder bonds 110. The pads 106 and the interconnect structures 108 may be composed of an electrically conductive material such as a metal (e.g., copper). In the depicted embodiment, the pads 106 are disposed on a surface of the PCB 102 that faces the die 104.

In some embodiments, the interconnect structures 108 may include pillar structures, as depicted, that extend to provide a majority of a gap distance, G2, between the PCB 102 and the die 104. In some embodiments, the interconnect structures 108 may include pads, bumps, posts, or other structures to facilitate electrical and/or mechanical coupling of the die 104 to the PCB 102. The interconnect structures 108 may extend to provide less than a majority of the gap distance G2 in some embodiments. The solder bonds 110 may include solder bumps in some embodiments. The solder bonds 110 may attach the interconnect structures 108 to the pads 106.

A fluxing underfill material 112 may be disposed on the PCB 102 between the die 104 and the PCB 102, as can be seen. The fluxing underfill material 112 may at least include a fluxing agent and an epoxy material. The fluxing agent may facilitate formation of the solder bonds 110 by, for example, removing oxidation from solderable surfaces. The fluxing agent may include, for example, organic acid groups that clean surfaces of the pads 106 and/or surfaces of the interconnect structures 108, which may include the solderable material (e.g., tin) disposed on a distal end or surface of the interconnect structures 108 in some embodiments. The fluxing agent may clean the surfaces of the interconnect structures 108 during a solder reflow process that forms the solder bonds 110 and/or the solder bonds 116. In some embodiments, the fluxing agent may include, for example, rosin, abiatic acid, ammonium chloride, and the like. The fluxing agent may include other materials in other embodiments.

The fluxing underfill material 112 may include an epoxy material that is configured to harden during the solder reflow process that forms the solder bonds 110 to mechanically strengthen the solder bonds 110 and prevent failure (e.g., cracking, breaking, or detaching) of the solder bonds 110 during subsequent thermal cycling or handling. In some embodiments, the epoxy material may include an epoxy resin and/or hardener that are configured to allow or facilitate curing or hardening of the epoxy material at a temperature (e.g., up to 260° C. or greater) associated with the solder reflow process. For example, the epoxy resin may be a B-stage epoxy (e.g., prepreg) material that hardens to a C-stage epoxy material at temperatures associated with the solder reflow process. The hardener may catalyze the hardening reactions of the epoxy resin at solder reflow temperatures.

The fluxing underfill material 112 may cover a surface of the PCB 102 that faces the die 104 between the die 104 and the PCB 102, as can be seen. The fluxing underfill material 112 may further encapsulate the solder bonds 110, alleviating stresses or other mechanical forces that may cause the solder bonds 110 to fail under subsequent thermal processes (e.g., during formation of sheet molding structures 118). The mechanical stresses or other forces may be due to mismatched CTEs of die 104 materials and PCB 102 materials that result in different expansion/contraction rates of the materials during heating/cooling processes. The fluxing underfill material 112 may absorb the stresses such that the stress transferred to the solder bonds 110 is reduced or eliminated. In some embodiments, the fluxing underfill material 112 may fill the region between the die 104 and the PCB 102 (e.g., such that the fluxing underfill material 112 is in direct contact with the die 104), as can be seen. The fluxing underfill material 112 may include additional materials or agents in some embodiments.

A sheet molding structure 118 may be formed on or over the PCB 102, as can be seen, to protect the components mounted on the PCB 102 from handling or other environmental hazards. The sheet molding structure 118 may further provide a surface for laser marking (e.g., laser markings 150) of the IC package 100. The sheet molding structure 118 may be composed of an epoxy material (e.g., B-stage material) that softens when heat is applied to the epoxy material. In some embodiments, the formation of the sheet molding structure 118 is performed at temperatures up to 175° C. The formation of the sheet molding structure 118 may be performed at other temperatures in other embodiments.

In some embodiments, the sheet molding structure 118 is formed by placing a surface of the sheet molding structure 118 on the components (e.g., die 104, passive components 114) mounted on the PCB 102 and applying heat to an opposite surface of the sheet molding structure 118 to cause the material of the sheet molding structure 118 to soften. Force may be applied to the sheet molding structure 118 and/or the PCB 102 to cause the softened sheet molding structure 118 to partially encapsulate the die 104 and/or passive components 114. For example, the sheet molding structure 118 may encapsulate an inactive surface of the die 104 that is disposed opposite to the active surface of the die 104 and may further encapsulate at least a portion of surfaces of the die 104 that are substantially perpendicular to the active/inactive surfaces of the die 104 (e.g., side surfaces 105), as can be seen.

In some embodiments, the sheet molding structure 118 has a thickness, T1. The thickness T1 may have a value ranging from 275 microns to 375 microns according to various embodiments. The sheet molding structure 118 may be formed to provide at least a distance, D1, between a surface of the tallest component (e.g., the inactive surface of the die 104 in FIG. 1) and an outer surface, S1, of the sheet molding structure 118. The distance, D1, may be a distance that allows laser marking (e.g., laser markings 150) of the outer surface S1 without breaching the sheet molding structure 118. In some embodiments, the distance D1 has a value from 25 microns to 100 microns.

The outer surface S1 of the sheet molding structure 118 may be separated from the PCB 102 by a distance, D2. The distance D2 may be less than or equal to 500 microns in some embodiments. An inner surface of the sheet molding structure 118 may be separated from the PCB 102 by a gap distance, G1. In some embodiments, the gap distance G1 has a value from 50 microns to 175 microns. An active surface of the die 104 may be separated from the PCB 102 by the gap distance, G2. In some embodiments, the gap distance G2 has a value from 55 microns to 65 microns. Other values for D1, D2, G1, G2 and T1 may be used in other embodiments.

As can be seen in FIG. 1, an air gap may separate the sheet molding structure 118 and the fluxing underfill material 112 in some embodiments. In other embodiments, the sheet molding structure 118 and the fluxing underfill material 112 may be in direct physical contact (e.g., the gap distance G1 is less than or equal to the gap distance G2).

In some embodiments, the gap distance G1 represents a minimum gap distance between the inner surface of the sheet molding structure 118 and the PCB 102. The gap distance G1 may have a value greater than 0 to provide an air gap between the sheet molding structure 118 and the PCB 102. The air gap between the sheet molding structure 118 and the PCB 102 may provide an escape path for any moisture trapped in voids that may exist in the fluxing underfill material 112. For example, when moisture in a void reaches an elevated temperature (e.g., boiling point of the moisture), the moisture may explode out of the void or otherwise exert pressure on surrounding structures (e.g., die 104, the interconnect structures 108, solder bonds 110, pads 106, PCB 102) resulting in failures of the solder bonds 110. The air gap between the sheet molding structure 118 and the PCB 102 may mitigate these harmful effects by providing an escape path for the moisture.

According to various embodiments, laser markings 150 may be formed into the outer surface S1 of the sheet molding structure 118. The laser markings 150 may have a depth of about 25 microns into the sheet molding structure 118 in some embodiments. The laser markings 150 may provide identification of the IC package 100. For example, the laser markings 150 may identify a product contained in the IC package 100, information that indicates when and/or where the product was fabricated, and/or an orientation indicator (e.g., pin 1 locator) to indicate an orientation of the IC package 100 to a machine configured to read the orientation indicator.

According to various embodiments, the outer surface S1 may be smooth to facilitate ease of automated assembly using pick-and-place equipment. For example, pick-and-place equipment may include pick-up nozzles equipped with vacuum to adhere to the smooth surface of the IC package 100 and place the IC package 100 into another product such as an electronic assembly or carrier.

Using a fluxing underfill material 112 in conjunction with the sheet molding structure 118 may eliminate a need to encapsulate a die (e.g., die 104) using a conventional transfer or compression molding compound that adheres to a package substrate and fully encapsulates the die (e.g., including an underfill region between the die and the package substrate). The fluxing underfill material 112 may increase solder joint reliability of the solder bonds 110 and provide a lower cost solution relative to transfer or compression molding techniques.

Embodiments of the present disclosure may further allow use of a larger panel size in fabricating the IC package 100, provide Moisture Sensitivity Level (MSL) 1 performance of the IC package 100, and allow closer spacing of components (e.g., passive components 114, die 104, pads 106, etc.) to one another on the PCB 102 allowing dimensions of the IC package 100 to shrink. The components may be spaced closer together by providing a fluxing underfill material 112 that eliminates a transfer molding process to encapsulate and underfill the die or underfill areas under passive components 114. Conventional processes (e.g., transfer molding or compression molding) to perform molding processes may require larger spacing than embodiments of the present disclosure.

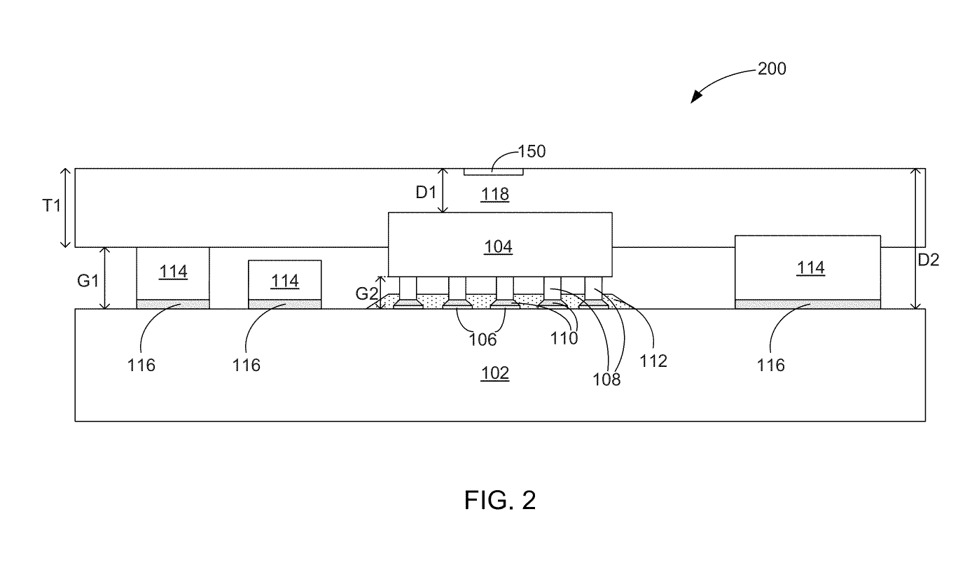

FIG. 2 schematically illustrates a cross-section side view of another example IC package 200 configuration including a fluxing underfill material 112 and a sheet molding structure 118, according to various embodiments. The IC package 200 may comport with embodiments described in connection with the IC package 100 of FIG. 1, except that in FIG. 2, an air gap may separate the fluxing underfill material 112 and the die 104.

The air gap between the die 104 and the fluxing underfill material 112 may provide an additional escape path for moisture that may be trapped in voids formed in the fluxing underfill material 112. The air gap between the die 104 and the fluxing underfill material 112 may further mitigate harmful effects (e.g., failure of solder bonds 110) associated with escaping moisture. In some embodiments, the fluxing underfill material 112 is disposed to cover the pads 106, the solder bonds 110 and a portion of the interconnect structures 108 to mechanically strengthen the solder bonds 110.

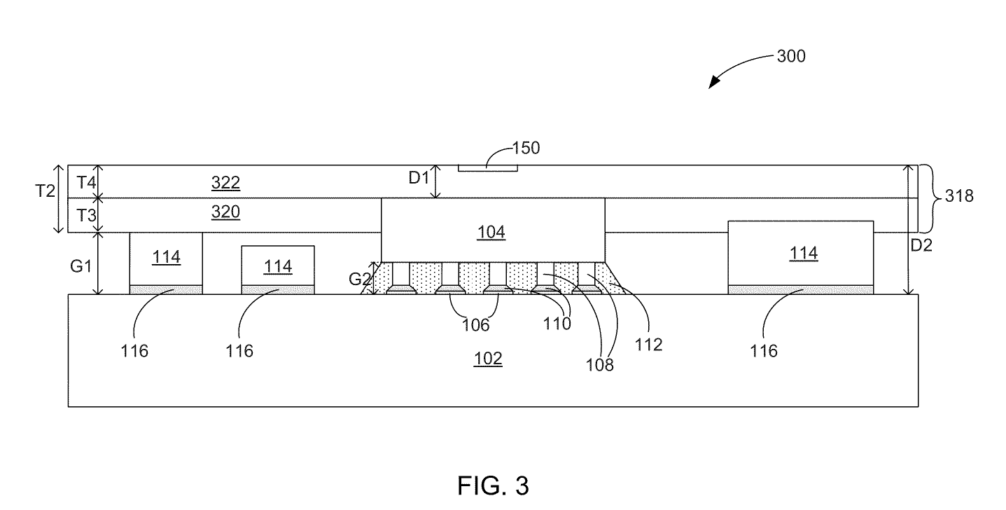

FIG. 3 schematically illustrates a cross-section side view of another example IC package 300 configuration including a fluxing underfill material 112 and a tape structure 318, according to various embodiments. The IC package 300 may comport with embodiments described in connection with IC package 100 of FIG. 1, except that a tape structure 318 may be used instead of a sheet molding structure 118.

According to various embodiments, the tape structure 318 may include at least two layers coupled together. A first layer 320 of the tape structure 318 may include a material that softens when heat is applied such as, for example, a B-stage epoxy material. A second layer 322 of the tape structure 318 may include a material that is fully cured or hardened such as, for example, a C-stage epoxy material. The second layer 322 may be referred to as an adhesive layer in some embodiments because it is configured to adhere to components (e.g., the die 104 in FIG. 3) mounted on the PCB 102.

The tape structure 318 may be formed by placing the tape structure 318 on the components (e.g., die 104 and passive components 114) mounted on the PCB 102. Heat may be applied to a surface (e.g., the outer surface of the second layer 322) of the tape structure 318 to soften the first layer 320 and force may be used to bring the tape structure 318 and the PCB 102 together such that the softened material of the first layer 320 encapsulates at least an inactive surface of the die 104. In some embodiments, the first layer 320 may further encapsulate at least a portion of surfaces of the die 104 that are substantially perpendicular to the active/inactive surfaces of the die 104, as can be seen. In some embodiments, the formation of the tape structure 318 is performed at temperatures up to 175° C. The formation of the tape structure 318 may be performed at other temperatures in other embodiments.

In some embodiments, the tape structure 318 may have a thickness, T2, ranging from 125 microns to 200 microns. For example, the first layer 320 may have a thickness, T3, ranging from 75 microns to 100 microns and the second layer 322 may have a thickness, T4, ranging from 50 microns to 100 microns. Thicknesses for T2, T3, and T4 may have other values in other embodiments.

The tape structure 318 may comport with embodiments described in connection with the sheet molding structure 118. For example, in some embodiments an air gap may separate the tape structure 318 and the fluxing underfill material 112 and, in other embodiments, the tape structure 318 may be in physical contact with the fluxing underfill material 112. In some embodiments, the gap distance G1 represents a minimum gap distance between the inner surface of the tape structure 318 and the PCB 102 and has a value greater than 0 to provide an air gap between the tape structure 318 and the PCB 102. The air gap between the tape structure 318 and the PCB 102 may provide an escape path for any moisture trapped in voids that may exist in the fluxing underfill material 112.

According to various embodiments, laser markings 150 may be formed into a surface of the tape structure 318, as can be seen. The laser markings 150 may have a depth of about 25 microns in some embodiments. According to various embodiments, the outer surface of the tape structure (e.g., surface of the second layer 322) may be smooth to facilitate ease of automated assembly using pick-and-place equipment. For example, pick-and-place equipment may include pick-up nozzles equipped with vacuum to adhere to the smooth surface of the IC package 300 and place the IC package 300 into another product such as an electronic assembly or carrier. The fluxing underfill material 112 may comport with embodiments described in connection with the fluxing underfill material 112 of FIGS. 1 and 2.

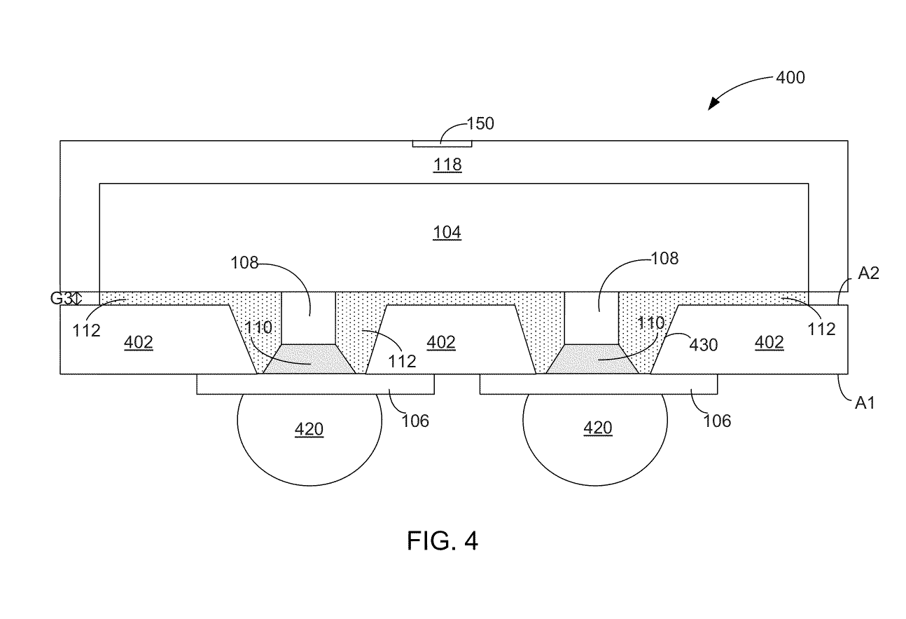

FIG. 4 schematically illustrates a cross-section side view of another example IC package 400 configuration including a fluxing underfill material 112 and a sheet molding structure 118, according to various embodiments. In some embodiments, the die 104, interconnect structures 108, solder bonds 110, pads 106, fluxing underfill material 112, sheet molding structure 118, and laser markings 150 may comport with embodiments described in connection with FIG. 1.

The IC package 400 may include a package substrate such as, for example, a flex tape 402. The flex tape 402 may include, for example, a single-sided flex tape. The flex tape 402 may be composed of polyimide in some embodiments and may include other suitable materials in other embodiments.

Pads 106 are formed on a first surface, A1, of the flex tape 402, as can be seen. One or more openings 430 are formed through the flex tape 402 between the first surface Al and a second surface, A2, of the flex tape 402. The second surface A2 of the flex tape 402 may face a die 104 mounted in a flip-chip configuration on the flex tape 402 using interconnect structures 108 and solder bonds 110 to couple the die 104 to the pads 106. The interconnect structures 108 and solder bonds 110 may be coupled to a backside of the pads 106 through the one or more openings 430 formed in the flex tape 402, as can be seen. Coupling the die 104 to the flex tape 402 in this manner, the die 104 may be precisely registered to the flex tape 402 and prevent movement of the die 104 relative to the flex tape 402 resulting in higher yields in the fabrication of the IC package 400 compared with techniques that merely place a die on flex tape and mold the die to the flex tape (e.g., fewer mistakes with forming laser markings 150 or singulating/sawing the IC package 400).

A sheet molding structure 118 (e.g., or in some embodiments a tape structure 318 as described in connection with FIG. 3) may be formed on the die 104. In some embodiments, an air gap having a gap distance, G3, may separate the sheet molding structure 118 and the flex tape 402. The air gap may between the sheet molding structure 118 and the flex tape 402 may provide an escape path for any moisture trapped in voids that may exist in the fluxing underfill material 112. In some embodiments, the gap distance G3 may be zero. That is, the sheet molding structure 118 may be in direct physical contact with the flex tape 402 to hermetically seal the die 104 in the IC package 400. The flex tape 402 and/or underfill material 112 may absorb mechanical stresses of materials of the IC package 400 during thermal processes associated with forming the sheet molding structure 118 or mechanical stresses associated with handling.

One or more package interconnect structures (e.g., solder balls 420) may be formed on the pads 106, as can be seen, to allow further electrical coupling of the IC package 400 with other electronic assemblies such as, for example, a motherboard assembly. In some embodiments, the IC package 400 may be configured to couple with other electronic assemblies in a ball grid array (BGA) or land grid array (LGA) configuration. In some embodiments, the IC package 400 may be a package for a single die. The die 104 may be a GaAs die in such embodiments. In other embodiments, the IC package 400 may be for multiple dies and/or passive components (e.g., passive components 114 of FIG. 1). The die 104 may include other types of dies in other embodiments. According to various embodiments, the IC packages 100, 200, 300, or 400 may be final products ready for shipping to a customer.

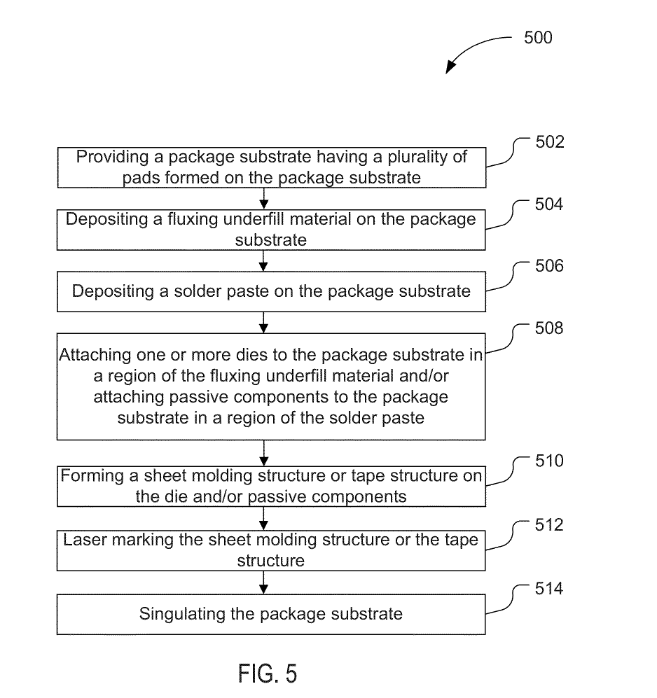

FIG. 5 is a flow diagram of a method 500 for fabricating an IC package (e.g., IC package 100, 200, 300, or 400) as described herein, according to various embodiments. The method 500 may comport with embodiments described in connection with FIGS. 1-4.

At 502, the method 500 includes providing a package substrate (e.g., PCB 102 of FIGS. 1-3 or flex tape 402 of FIG. 4) having a plurality of pads (e.g., pads 106 of FIGS. 1-4) formed on the package substrate. The plurality of pads may be configured to receive a corresponding plurality of interconnect structures (e.g., interconnect structures 108 of FIGS. 1-4) formed on one or more dies (e.g., die 104 of FIGS. 1-4) that are to be coupled to the package substrate in a flip-chip configuration. In some embodiments, the package substrate may include a plurality of solder-on-pads (SOPs). The SOPs may have solderable material disposed on a surface of the pads to form solder bonds (e.g., solder bonds 110 or 116 of FIGS. 1-4) with the interconnect structures of the one or more dies or passive components. In other embodiments, the solderable material may be deposited or disposed on the interconnect structures of the one or more dies.

At 504, the method 500 includes depositing a fluxing underfill material (e.g., the fluxing underfill material 112 of FIGS. 1-4) on the package substrate. The fluxing underfill material may, for example, be deposited by a stencil print process. Equipment configured to hold the package substrate may precisely position the package substrate adjacent to a metal stencil, which may vary in thickness (e.g., from 70 microns to 150 microns). The fluxing underfill material may be placed on a top of the stencil and a metal squeegee may push the fluxing underfill material across the top of the stencil to fill openings formed in the stencil (e.g., the openings may be formed by laser or chemical treatment). After the squeegee passes by the openings and comes to rest, the package substrate may be removed from the stenciling equipment with the fluxing underfill material positioned on regions of the package substrate where the one or more dies are to be coupled. Other suitable techniques to deposit the fluxing underfill material may be used in other embodiments.

In embodiments where passive components (e.g., passive components 114 of FIGS. 1-3) are coupled to the package substrate, the method 500 may further include, at 506, depositing a solder paste on the package substrate. The solder paste may be deposited by a stencil printing process as described herein. The solder paste may be deposited on regions of the package substrate where the passive components are to be coupled. Other suitable techniques to deposit the solder paste may be used in other embodiments. In other embodiments, the package substrate may include SOPs that are configured to receive the passive components.

At 508, the method 500 may further include attaching one or more dies to the package substrate in a region of the deposited fluxing underfill material and/or attaching passive components to the package substrate in a region of the solder paste. The die may, for example, be positioned or placed relative to the package substrate such that the solderable material is in contact with or within solderable distance of the pads and the interconnect structures of the die. The solderable material may be disposed on the interconnect structures or the pads (e.g., SOPs) as described herein. The passive components may be positioned or placed relative to the package substrate within solderable distance of the solder paste.

A solder reflow process may be performed to soften and harden the solderable material to form the solder bonds between the one or more dies and the package substrate and/or between the passive components and the substrate. The solder reflow process may be a single solder reflow process that simultaneously forms the solder bonds between the one or more dies and the package substrate and between the passive components and the substrate in some embodiments. The single solder reflow process may further simultaneously cure or harden the epoxy material of the fluxing underfill material. The fluxing agent of the fluxing underfill material may clean solderable surfaces (e.g., remove oxidation from the interconnect structures and/or pads) during the single solder reflow surface. The solder reflow process may include application of heat to provide a solder reflow temperature up to 260° C. in some embodiments. The solder reflow process may include temperatures that are higher or lower than 260° C. in other embodiments.

At 510, the method 500 may further include forming a sheet molding structure (e.g., sheet molding structure 118 of FIGS. 1-2 and 4) or tape structure (e.g., tape structure 318 of FIG. 3) on the die and/or passive components. The sheet molding structure or the tape structure may be formed, for example, by placing the sheet molding structure or the tape structure on the one or more dies and/or passive components mounted on the package substrate, and applying heat to soften material of the sheet molding structure or tape structure. The process to form the sheet molding structure or the tape structure may include applying heat to provide temperatures up to 175° C. in some embodiments. Other temperatures may be used to form the sheet molding structure or the tape structure in other embodiments. Force may be applied to the sheet molding structure or the tape structure and/or the package substrate to cause the softened material to encapsulate a portion of the one or more dies and/or the passive components as described herein. An air gap may be provided between the sheet molding structure or the tape structure and the package substrate such that the sheet molding structure or the tape structure and the package substrate do not physically contact one another to provide an escape path for moisture that may be trapped in voids of the fluxing underfill material.

According to various embodiments, one or more cleaning operations (e.g., clean, dry, and/or plasma clean operations) may be used to remove flux residue from a surface of the package substrate to facilitate or allow adherence of the sheet molding structure or the tape structure to the package substrate (e.g., when gap distance G1 of FIGS. 1-3 or gap distance G3 of FIG. 4 is zero). In other embodiments where an air gap is provided between the sheet molding structure or the tape structure and the package substrate (e.g., when gap distance G1 of FIGS. 1-3 or gap distance G3 of FIG. 4 is greater than zero), the cleaning operations may not be needed to clean the surface of the package substrate. In some embodiments, no cleaning operations are performed on the package substrate subsequent to performing the solder reflow process and prior to forming the sheet molding compound or the tape structure.

At 512, the method 500 may further include laser marking the sheet molding structure or the tape structure. A surface of the sheet molding structure or the tape structure may be laser marked to indicate information about components of the IC package.

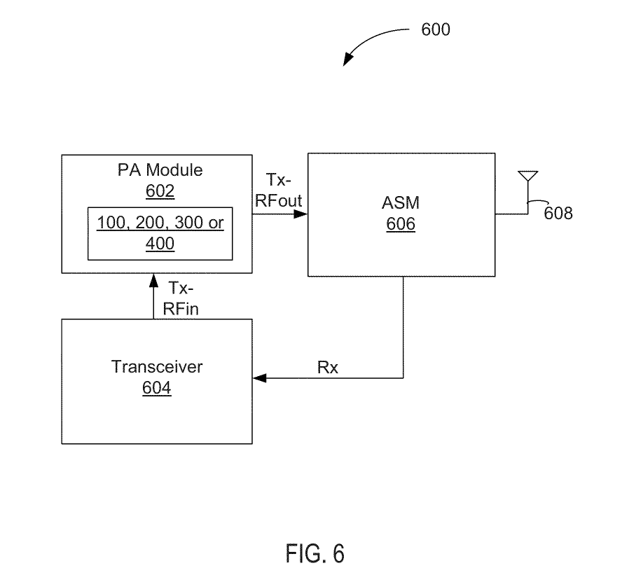

At 514, the method 500 may further include singulating the package substrate. In some embodiments, the IC package may be formed on a package substrate that is physically coupled with a plurality of other package substrates in a matrix array of package substrates. That is, multiple IC packages may be simultaneously formed on the package substrates of the matrix array using principles described herein. The package substrate may be singulated from the other package substrates of the matrix array using any suitable technique including, for example, sawing or laser-cutting. The singulated package substrate may subsequently be shipped to a customer or placed into another electronic assembly (e.g., system 600 of FIG. 6).

Embodiments of an IC package (e.g., IC package 100, 200, 300 or 400 of FIGS. 1-4) described herein may be incorporated into various other systems. The IC package may include, for example, a flip-chip module, a surface acoustic wave (SAW) module, or a filter bank module, or combinations thereof, in some embodiments.

A block diagram of an example system 600 is illustrated in FIG. 6. As illustrated, the system 600 includes a power amplifier (PA) module 602, which may be a Radio Frequency (RF) PA module in some embodiments. The system 600 may include a transceiver 604 coupled with the power amplifier module 602 as illustrated. The power amplifier module 602 may include an IC package described herein.

The power amplifier module 602 may receive an RF input signal, RFin, from the transceiver 604. The power amplifier module 602 may amplify the RF input signal, RFin, to provide the RF output signal, RFout. The RF input signal, RFin, and the RF output signal, RFout, may both be part of a transmit chain, respectively noted by Tx-RFin and Tx-RFout in FIG. 6.

The amplified RF output signal, RFout, may be provided to an antenna switch module (ASM) 606, which effectuates an over-the-air (OTA) transmission of the RF output signal, RFout, via an antenna structure 608. The ASM 606 may also receive RF signals via the antenna structure 608 and couple the received RF signals, Rx, to the transceiver 604 along a receive chain.

In various embodiments, the antenna structure 608 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 600 may be any system including power amplification. The IC package may include components (e.g., die 104 of FIGS. 1-4) that may provide an effective switch device for power-switch applications including power conditioning applications such as, for example, Alternating Current (AC)-Direct Current (DC) converters, DC-DC converters, DC-AC converters, and the like. In various embodiments, the system 600 may be particularly useful for power amplification at high radio frequency power and frequency. For example, the system 600 may be suitable for any one or more of terrestrial and satellite communications, radar systems, and possibly in various industrial and medical applications. More specifically, in various embodiments, the system 600 may be a selected one of a radar device, a satellite communication device, a mobile handset, a cellular telephone base station, a broadcast radio, or a television amplifier system.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

1-14. (canceled)

15. A method, comprising:
providing a package substrate having a plurality of pads formed on the package substrate, the plurality of pads being configured to receive a corresponding plurality of interconnect structures formed on a die; and
depositing a fluxing underfill material on the package substrate, the fluxing underfill material comprising a fluxing agent configured to facilitate formation of solder bonds using a solderable material between individual interconnect structures of the plurality of interconnect structures and individual pads of the plurality of pads and an epoxy material configured to harden during formation of the solder bonds to mechanically strengthen the solder bonds.

16. The method of claim 15, further comprising:
attaching the die to the package substrate in a flip-chip configuration.

17. The method of claim 16, wherein attaching the die to the package substrate comprises:
positioning the die relative to the package substrate such that the solderable material is disposed between the individual interconnect structures and the individual pads; and
performing a single solder reflow process to form the solder bonds between the individual interconnect structures and the individual pads and to harden the epoxy material of the fluxing underfill material.

18. The method of claim 17, wherein the fluxing agent is configured to facilitate formation of the solder bonds by removing oxidation from solderable surfaces of the individual interconnect structures and the individual pads during the single solder reflow process.

19. The method of claim 17, further comprising:
prior to performing the single solder reflow process, depositing a solder paste on a region of the package substrate where one or more passive components are to be mounted; and
positioning the one or more passive components in contact with the solder paste, wherein performing the single solder reflow process forms solder bonds between the one or more passive components and the package substrate.

20. The method of claim 17, further comprising:
forming a sheet molding structure or tape structure on the die to encapsulate an inactive surface of the die and at least a portion of surfaces of the die that are substantially perpendicular to the inactive surface of the die, wherein an air gap separates the sheet molding structure or the tape structure and the package substrate.

21. The method of claim 20, wherein the method includes forming the sheet molding structure, the sheet molding structure being formed by:
placing a B-stage epoxy material on the die;
applying heat to a surface of the B-stage epoxy material; and
applying force to bring the B-stage epoxy material and the die together to cause the B-stage epoxy material to encapsulate the inactive surface of the die and at least a portion of the surfaces of the die that are substantially perpendicular to the inactive surface of the die.

22. The method of claim 21, wherein:
applying heat to the surface of the B-stage epoxy material is performed at temperatures up to 175° C.; and
performing the single solder reflow process includes applying heat to the solderable material at temperatures up to 260° C.

23. The method of claim 20, wherein no cleaning processes are performed on the package substrate subsequent to performing the single solder reflow process and prior to forming the sheet molding structure or the tape structure.

24. The method of claim 20, further comprising:
laser marking the sheet molding structure or the tape structure.

25. The method of claim 15, wherein providing a package substrate having a plurality of pads comprises:
providing a package substrate having a plurality of solder-on-pads (SOPs) having the solderable material disposed on a surface of the pads.
